(19) United States
(12) Patent Application Publication
(10) Pub. No.: US 2004/0227237 A1
(43) Pub. Date: Nov. 18, 2004

(54) Semiconductor apparatus and method of manufactuing the same

(76) Inventor: Naohiro Ueda, Hyougo-ken (JP)

Correspondence Address: DICKSTEIN SHAPIRO MORIN & OSHINSKY LLP, 2101 L STREET NW, WASHINGTON, DC, 20037-1526, US

(21) Appl. No.: 10/801,838

(22) Filed: Mar. 17, 2004

(30) Foreign Application Priority Data
Mar. 19, 2003 (JP) 2003-074881

(51) Int. Cl. H01L 23/48

(52) U.S. Cl. 257/734

(57) ABSTRACT

A semiconductor apparatus includes, in one example, a semiconductor substrate, an electrode pad, a MOS transistor, and an analog circuit. The electrode pad includes a metal layer and is formed on the semiconductor substrate. The MOS transistor also is formed on the semiconductor substrate. The analog circuit is formed in a region under the electrode pad on the semiconductor substrate and has a resistive element including a semiconductor material. A method is also described for manufacturing a semiconductor apparatus including a MOS transistor and an analog circuit having a resistive element of a semiconductor material.

This patent specification is based on Japanese patent applications No. JPAP2003-074881 filed on Mar. 19, 2003, the entire contents of which are incorporated by reference herein.

### BACKGROUND OF THE INVENTION

1. Field of the Invention

The present invention relates to a semiconductor apparatus and a method of manufacturing the semiconductor apparatus, and more particularly to a semiconductor apparatus having a MOS (metal oxide semiconductor) transistor and an analog circuit including a resistive element and a method of manufacturing the same.

2. Discussion of the Background

A typical conventional semiconductor apparatus is illustrated in FIGS. 1A and 1B. FIG. 1A is a top plan view of the conventional semiconductor apparatus and FIG. 1B is a cross-section view of the conventional semiconductor apparatus of FIG. 1A seen from a line A-A of FIG. 1A.

As illustrated in FIG. 1B, the semiconductor apparatus includes a semiconductor substrate 2 made of silicon on which a LOCOS (local oxidation of silicon) oxide film 3 is formed. On the semiconductor substrate 2 and the LOCOS oxide film 3, an insulating interlayer 89 is formed. An electrode pad 91 is formed on the insulating interlayer 89 in a formation region of the electrode pad. A final protection film 93 is formed on the insulating interlayer 89 and on the electrode pad 91. A pad window 95 is formed in the final protection film 93 at a position corresponding to the electrode pad 91.

As illustrated in FIG. 1B, the conventional semiconductor apparatus has no device arranged in a region under the electrode pad 91.

Although FIG. 1B illustrates an example of single-layered metal wiring, examples of multi-layered metal wiring can also be considered in the same way. That is, in a multi-layered wiring structure, an electrode pad is formed based on an uppermost metal wiring layer.

In a manufacturing process of the above-mentioned conventional semiconductor apparatus, a wire bonding assembly is performed relative to the electrode pad. That is, in the assembling process, a lead frame of the package and an electrode pad are connected to each other with a bonding wire.

FIG. 2 is a cross-sectional view of the conventional semiconductor apparatus after the packaging process. FIGS. 3A and 3B illustrate the conventional semiconductor apparatus of FIG. 2 after the wire bonding process. FIG. 3A is a cross-sectional view and FIG. 3B is a photo view.

As illustrated in FIG. 2, in the conventional semiconductor apparatus, a chip 99 is disposed on a die pad 97. Lead frames 101 are mounted around the die pad 97. The electrode pads (not shown in FIG. 2) provided to the chip 99 and the respective lead frames 101 are electrically connected with bonding wires 103. The die pad 97, the chip 99, the lead frames 101, and the bonding wires 103 are sealed with a molded resin 105. Each of the lead frames 101 has a leg side opposite to the side of the chip 99 outside the molded resin 105.

It is known that the connection of the bonding wire 103 to the electrode pad 91 by the wire bonding is attended with a relatively strong impact. The impact is directly transmitted to the semiconductor chip and therefore it is a common safeguard to arrange devices in regions other than under the electrode pad 91.

On the other hand, due to a recent realization of techniques for a multi-layered metal wiring, multi-layered metal wiring and an insulating film are disposed between the electrode pad 91 and the semiconductor substrate 2 and therefore the impact from the wire bonding is not directly transmitted to a nearby device.

In a five-layered metal wiring structure, for example, as illustrated in FIG. 4, the insulating interlayer 89, a first-layered metal wiring layer 29-1, a second-layered metal wiring layer 29-2, a third-layered metal wiring layer 29-3, and a fourth-layered metal wiring layer 29-4 are disposed between the electrode pad 91 structured by a fifth metal wiring layer arranged on the fourth metal wiring layer 29-4 and the semiconductor substrate 2.

In the multi-layered metal wiring structure, devices have been arranged in a region under the electrode pad since the impact of the wire bonding is not directly transmitted to the device, as described above.

In one example of such a semiconductor apparatus having the device arranged under the electrode pad, an input protection element is disposed under the electrode pad.

For example, one exemplary semiconductor circuit has an electrostatic destruction protection layer made of a resistor or a resistor and a diode. A tip of the electrostatic destruction protection layer is connected to the electrode pad and another tip thereof is electrically connected to an internal circuit so that an electric connection between the electrode pad and the internal circuit is achieved through the electrostatic destruction protection layer.

In another semiconductor apparatus, a punch through element and a protection element for the transistor are alternately arranged under areas around the edge sides of lower-layered metal wiring of an octagonal electrode pad. The octagonal electrode pad includes upper-layered metal wiring and lower-layered metal wiring formed on a P-well region of a P-type semiconductor substrate. In addition, a ring-shaped lower-layered metal wiring discharge line is disposed around the lower-layered metal wiring, and two N-type diffusion layers serving as the protection elements are respectively connected to the lower-layered metal wiring and the lower-layered metal wiring discharge line via contacts.

As described above, there are several semiconductor apparatuses having devices disposed under the electrode pad. However, such devices mainly provide input protection and do not perform an important operation in an actual integrated circuit.

In the conventional semiconductor apparatus having a resistive element made of a semiconductor material such as polysilicon, the resistive element may be contaminated with water from air entering through the insulating layer disposed on the resistive element when the package is left standing for a relatively long time period. Also, the resistive element may be contaminated with an impurity ion included in the upper-sided films. As a result of these contaminations, the resistance value of the resistive element is changed. In particular, when insulating films such as BPSG (boro-phospho silicate glass) film and SiN (silicon nitride) films are formed using a plasma CVD (chemical vapor deposition) method, a problem may occur such that the resistive element is contaminated with a hydrogen ion included in the PSG film or the SiN film.

### SUMMARY OF THE INVENTION

This patent specification describes a novel semiconductor apparatus which includes, in one example, a semiconductor substrate, an electrode pad, a MOS transistor, and an analog circuit. The electrode pad includes a metal layer and is formed on the semiconductor substrate. The MOS transistor also is formed on the semiconductor substrate. The analog circuit is formed in a region under the electrode pad on the semiconductor substrate and has a resistive element including a semiconductor material.

The resistive element may include a specific material made of one of polysilicon, silicon germanium, and silicon chrome.

The resistive element may include a plurality of resistors.

The MOS transistor may include a gate electrode including the specific material of the resistive element.

The above-mentioned semiconductor apparatus may further include an insulating film formed on the semiconductor substrate in a region in a vicinity of the electrode pad and a fuse element formed on the insulating film.

The insulating film may include the specific material of the resistive element.

The above-mentioned semiconductor apparatus may further include a rerouting layer formed in a region above the fuse element and an external connection terminal formed on the rerouting layer in a region different from a formation region of the electrode pad.

The analog circuit may include a voltage setting circuit, the resistive element may include at least two resistors for producing a split voltage based on an input source power voltage, and the voltage setting circuit may change the split voltage according to a condition of the fuse element.

The resistive element may include at least two resistors for producing a split voltage based on an input source power voltage, the analog circuit may include a reference voltage generator for generating a reference voltage and a voltage detector including a comparator for performing a comparison of the split voltage with the reference voltage.

The analog circuit may further include an output driver for controlling an output voltage based on an input voltage, and the comparator of the voltage detector may output a gate control voltage as a result of the comparison for controlling the output driver to control the output voltage.

This patent specification further describes a novel method of manufacturing a semiconductor apparatus including a MOS transistor and an analog circuit having a resistive element including a semiconductor material. In one example, a novel method includes the steps of providing a semiconductor substrate, forming an insulating film, forming a semiconductor material film, implanting an impurity, forming a resistive element, forming a first insulating layer, and forming an electrode pad. The step of forming an insulating film forms an insulating film on the semiconductor substrate. The step of forming a semiconductor material film forms a semiconductor material film on an entire surface of the semiconductor substrate including a formation region of the insulating film. The step of implanting an impurity implants an impurity to the semiconductor material film to acquire a predetermined resistance value. The step of forming a resistive element forms a resistive element on the insulating film by patterning the semiconductor material film. The step of forming a first insulating layer forms a first insulating layer on an entire surface of the semiconductor substrate including a formation region of the resistive element. The step of forming an electrode pad forms an electrode pad including a metal layer on the first insulating layer including a formation region of the resistive element.

The resistive element may include a specific material made of one of polysilicon, silicon germanium, and silicon chrome.

The step of forming the resistive element may form the resistive element in a predetermined formation region of the resistive element and the resistive element includes a plurality of resistors.

The above-mentioned method may further include the steps of forming a second insulating layer, forming a rerouting layer, and forming an external connection terminal. The step of forming a second insulating layer forms a second insulating layer having an opening at a position corresponding to a formation region of the electrode pad after the step of forming the electrode pad. The step of forming a rerouting layer forms a rerouting layer on the electrode pad and the second insulating layer. The step of forming an external connection terminal forms an external connection terminal on the rerouting layer in a region different from the formation region of the electrode pad.

The step of forming the resistive element may form a gate electrode on the insulating film in a formation region of the MOS transistor based on the semiconductor material film.

The step of forming the resistive element may form a fuse element on the insulating film in a region different from the formation region of the resistive element based on the semiconductor material film.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1A is a top plan view of a conventional semiconductor apparatus;

FIG. 1B is a cross-sectional view of the conventional semiconductor apparatus of FIG. 1A;

FIG. 2 is illustrates the conventional semiconductor apparatus of FIGS. 1A and 1B after being packaged;

FIG. 3A is a cross-sectional view of the conventional semiconductor apparatus of FIGS. 1A and 1B after being bonded with a bonding wire;

FIG. 3B is an electron microscopic picture of the bonding wire bonded to the conventional semiconductor apparatus of FIGS. 1A and 1B;

FIG. 4 is a cross-sectional view of a conventional semiconductor apparatus having a five-layered metal wiring structure;

FIG. 5A is a top plan view of a semiconductor apparatus according to an embodiment of the present invention;

FIG. 5B is a cross-sectional view of the semiconductor apparatus of FIG. 5A;

FIG. 6 is another cross-sectional view of the semiconductor apparatus of FIG. 5A;

FIG. 7A is a diagram showing an exemplary layout of the semiconductor apparatus of FIG. 5A;

FIG. 7B is a diagram showing an exemplary layout of the conventional semiconductor apparatus of FIG. 1A;

FIG. 7C is a diagram showing in an enlarged form an electrode pad included in the layout of the semiconductor apparatus of FIG. 5A;

FIGS. 8A-8C are cross-sectional views of the semiconductor apparatus of FIG. 5A in respective subsequent manufacturing processes;

FIGS. 9A and 9B are cross-sectional views of the semiconductor apparatus of FIG. 5A in respective subsequent manufacturing processes after the processes of FIGS. 8A-8C;

FIG. 10 is a top plan view of a region around a resistive-element formation region in the semiconductor apparatus of FIG. 5A after a formation process of a masking oxide film used when a low-resistance polysilicon film is formed;

FIG. 11 is a cross-sectional view of a resistive element formation region and an electrode pad formation region of a semiconductor apparatus having a five-layered metal wiring structure according to another embodiment of the present invention;

FIG. 12 is a cross-sectional view of a semiconductor apparatus according to another embodiment of the present invention;

FIGS. 13A-13C are cross-sectional views of the semiconductor apparatus of FIG. 12 in respective subsequent manufacturing processes;

FIG. 14 is an analog circuitry diagram of a constant voltage generator included in the semiconductor apparatus of FIG. 5A;

FIG. 15 is an analog circuitry diagram of a voltage detector included in the semiconductor apparatus of FIG. 5A;

FIG. 16 is an analog circuitry diagram of a voltage setting circuit included in the semiconductor apparatus of FIG. 5A;

FIG. 17 illustrates a fuse element portion of the voltage setting circuit of FIG. 16;

FIG. 18 illustrates a resistive element portion of the voltage setting circuit of FIG. 16;

FIG. 19 is an analog circuitry diagram of a voltage setting circuit with four fuse elements included in the semiconductor apparatus of FIG. 5A;

FIG. 20 is an analog circuitry diagram of the voltage setting circuit with one of the four fuse elements cut;

FIG. 21 is an analog circuitry diagram of the voltage setting circuit with all of the four fuse elements cut; and

FIG. 22 is a graph showing a relationship between combinations of the cut fuse elements and output voltages.

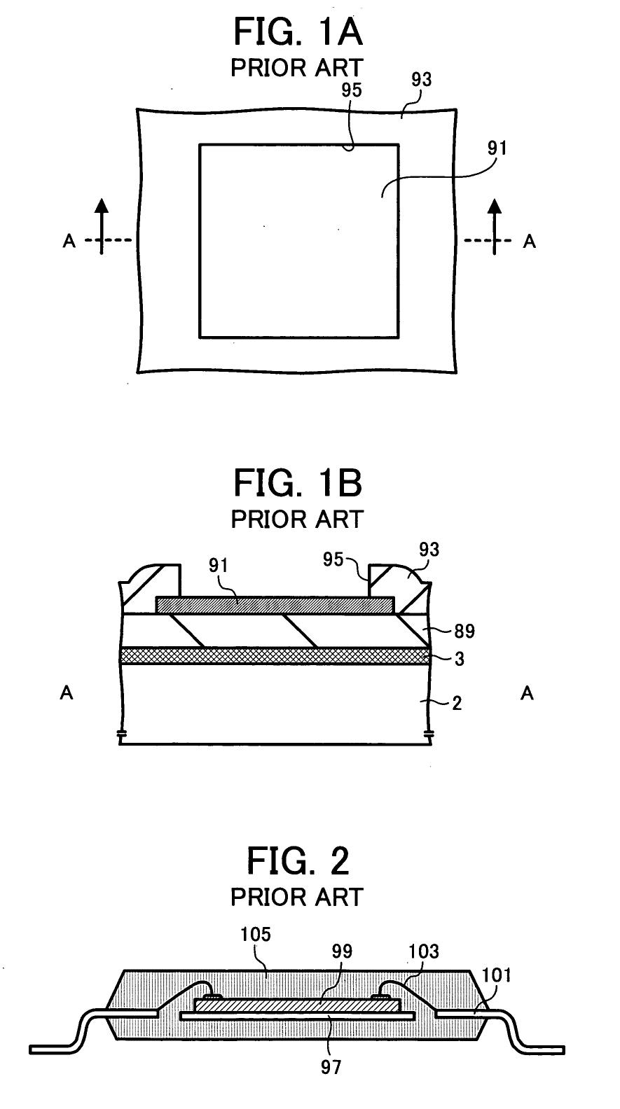

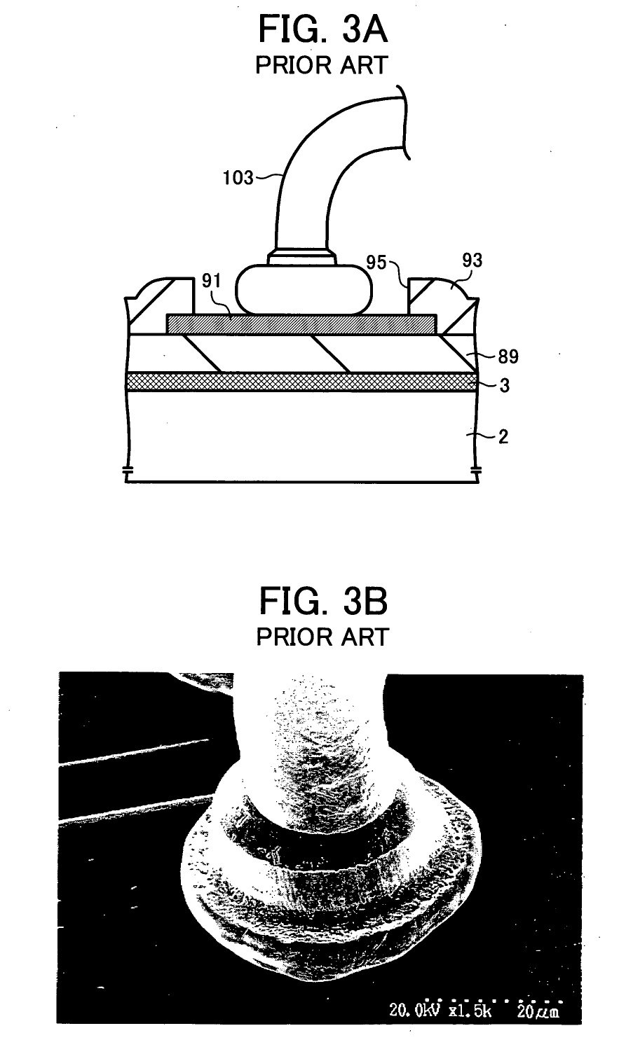

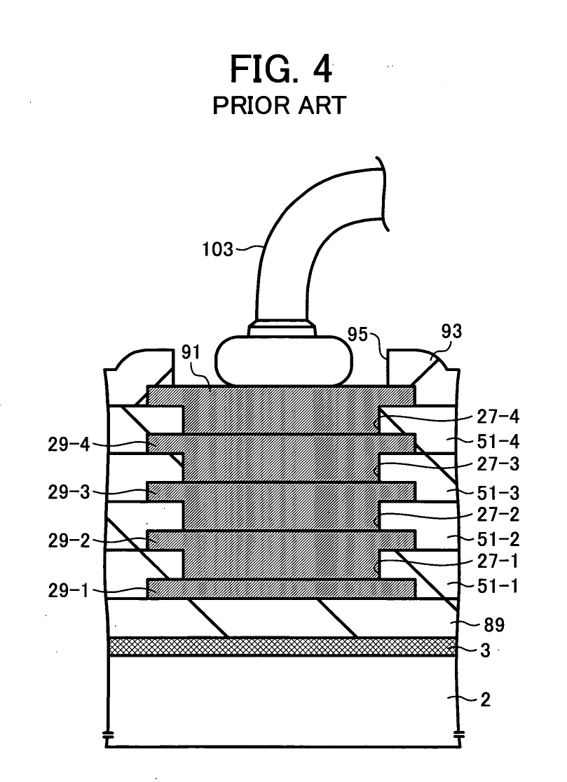

### DETAILED DESCRIPTION OF PREFERRED EMBODIMENTS

In describing preferred embodiments illustrated in the drawings, specific terminology is employed for the sake of clarity. However, the disclosure of this patent specification is not intended to be limited to the specific terminology so selected and it is to be understood that each specific element includes all technical equivalents that operate in a similar manner.

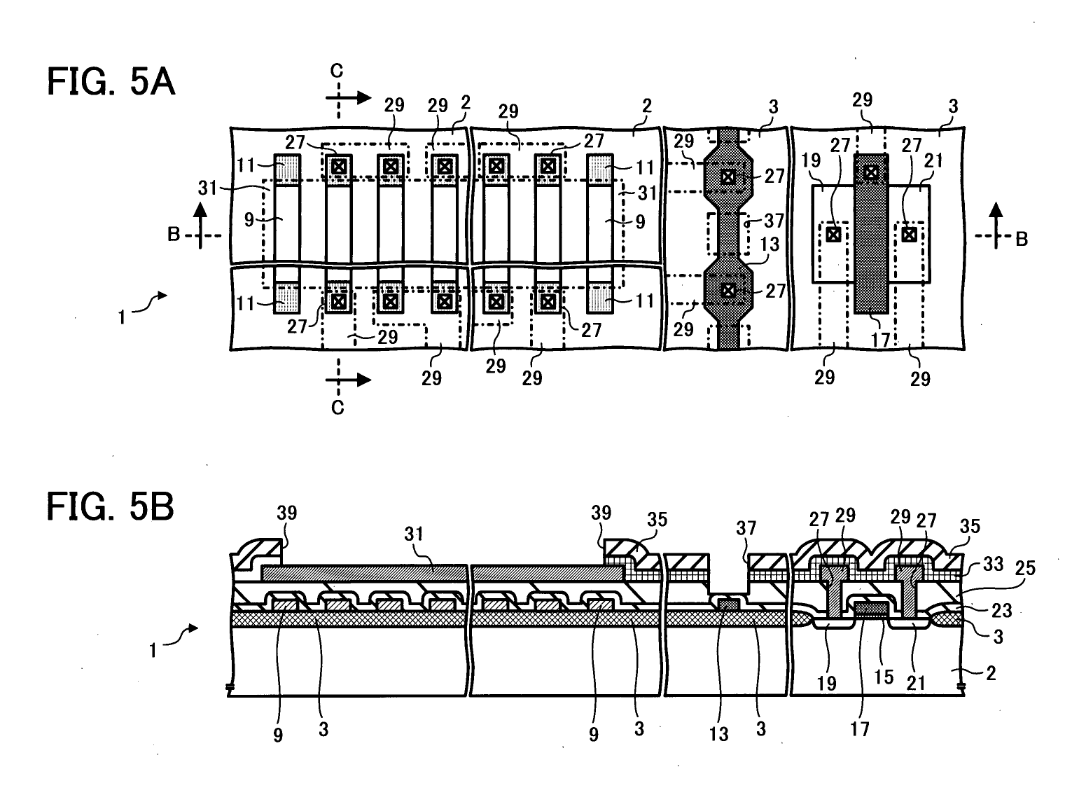

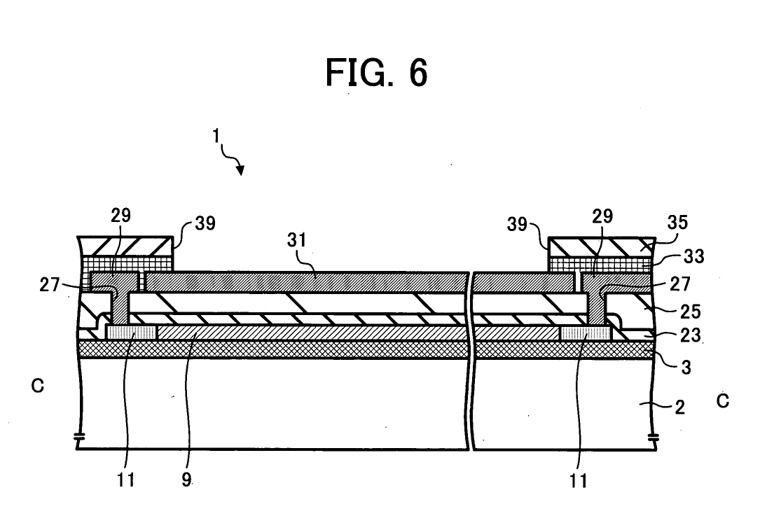

Referring now to the drawings, wherein like reference numerals designate identical or corresponding parts throughout the several views, and particularly to FIGS. 5A, 5B and 6, a semiconductor apparatus 1 according to an embodiment of the present invention is shown. FIG. 5A illustrates a top plan view of the semiconductor apparatus 1 and FIG. 5B a cross-sectional view of the semiconductor apparatus 1 taken on line B-B of FIG. 5A. FIG. 6 illustrates a cross-sectional view of the semiconductor apparatus 1 taken on line C-C of FIG. 5A. In FIG. 6, the several resistors, fuse elements, and MOS transistors of the apparatus are exemplified by the individual components shown. In FIG. 5A, an insulating interlayer is omitted for clarity. A layout of the semiconductor apparatus 1 with respect to the fuse elements and the MOS transistors relative to the resistors shown in FIG. 5A is but one example and the invention is not limited to it.

The semiconductor apparatus 1 includes a silicon semiconductor substrate 2 on which a LOCOS (local oxidation of silicon) oxide film 3 is disposed for separation of elements. The LOCOS oxide film 3 is formed with a LOCOS method.

As shown in FIG. 5A, a plurality of strip-shaped polysilicon resistors 9 is disposed in a resistive-element formation region on the LOCOS oxide film 3. The polysilicon included in the resistors 9 is impregnated with an impurity such as phosphorous to impart a specific value of resistance. At positions immediately next to both lengthwise ends of each one of the plurality of resistors 9, a low-resistance polysilicon region 11 is formed, including a polysilicon film impregnated densely with an N-type impurity such as phosphorous. The low-resistance polysilicon regions 11 allow the resistors 9 to acquire potentials.

A fuse element 13 including a polysilicon film is formed in a fuse-element formation region on the LOCOS oxide film 3. The polysilicon film included in the fuse element 13 is impregnated densely with an N-type impurity such as phosphorous so as to have a relatively low resistance.

As shown in FIG. 5A, a strip-shaped gate electrode 17 including polysilicon is formed via a gate oxide film 15 in a MOS transistor formation region surrounded by the LOCOS oxide film 3 on the semiconductor substrate 2. The gate electrode 17 has lengthwise ends both being bent slightly upwards to ride on the LOCOS oxide film 3. The gate electrode 17 is impregnated densely with an N-type impurity such as phosphorous so as to have a relatively low resistance.

A source diffusion layer 19 and a drain diffusion layer 21 which include an N-type impurity such as phosphorous or arsenic are formed at positions to laterally sandwich the formation region of the gate electrode 17 in the MOS transistor formation region on the semiconductor substrate 2.

An insulating interlayer including an NSG (non-doped silicate glass) film 23 disposed as a lower layer and a BPSG (boro-phospho silicate glass) film 25 disposed as an upper layer is formed on an entire upper surface of the semiconductor substrate 2 including upper regions of the resistors 9, the fuse element 13, and the gate electrode 17.

The NSG film 23 and the BPSG film 25 are provided with connection holes 27 at positions corresponding to the low-resistance polysilicon regions 11, the fuse element 13, the gate electrode 17, the source diffusion layer 19, and the drain diffusion layer 21. Two of the plurality of resistors 9 disposed at outermost positions in their aligned layout are dummy patterns and therefore no connection hole is provided at the positions corresponding to the low-resistance polysilicon regions 11 for such dummy patterns, as illustrated in FIG. 5A. The dummy patterns are provided to prevent entry of external hydrogen and a change of performance due to a concentration of mechanical stress.

A metal wiring layer 29 is provided in the connection holes 27 and on the BPSG film 25. The metal wiring layer 29 includes an Al-Si alloy including Si of approximately 1 wt % (weight percent).

An electrode pad 31 including a material equivalent to the material of the metal wiring layer 29 is formed in an electrode-pad formation region surrounding the formation region of the resistors 9 on the BPSG film 25.

A passivation film including, for example, a PSG (phosphor silicate glass) film 33 disposed as a lower layer and an SiN (silicon nitride) film 35 disposed as an upper layer is formed on the metal wiring layer 29, electrode pad 31, and the BPSG film 25.

A trimming window 37 and a pad window 39 are formed at positions corresponding to the fuse element 13 and the electrode pad 31 in the NSG film 23, the BPSG film 25, the PSG film 33, and the SiN film 35.

In this example, the resistors 9 are arranged under the electrode pad 31 and therefore it is possible to prevent contamination by ion impurities, charges, moisture, and hydrogen to the resistors 9 from a side above the electrode pad 31. This stabilizes the resistance values of the resistors 9.

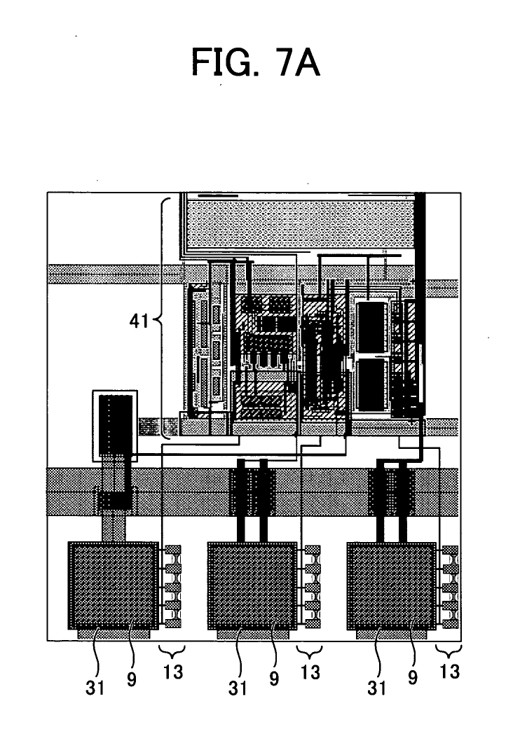

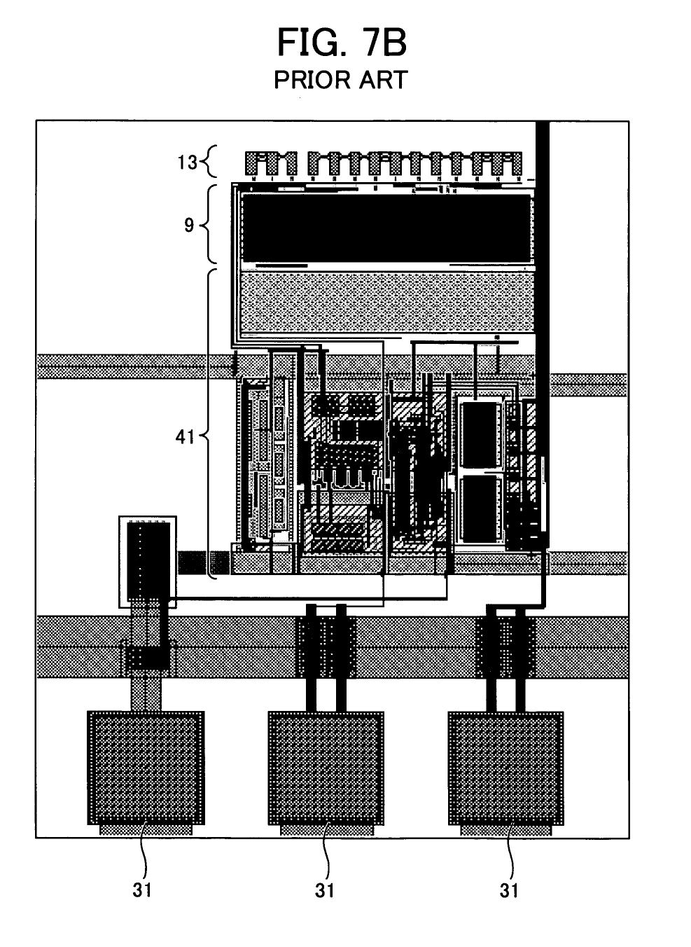

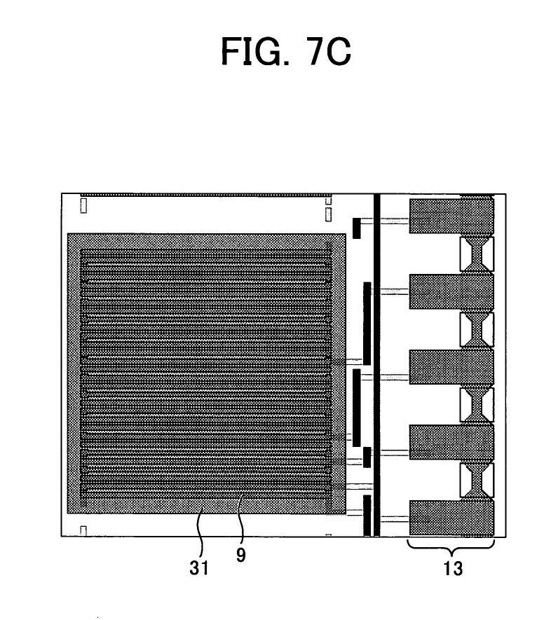

FIGS. 7A-7C illustrate an exemplary layout of the semiconductor apparatus 1 including the resistors 9, the fuse element 13, and the MOS transistor. FIG. 7A illustrates the semiconductor apparatus 1 according to an embodiment of the present invention, FIG. 7B a conventional example of the semiconductor device, and FIG. 7C a region around the electrode pad of the semiconductor apparatus 1 in an enlarged form.

In the conventional example of FIG. 7B, an internal circuit 41 including the MOS transistor, the plurality of resistors 9, the plurality of fuse elements 13, and the plurality of electrode pads 31 are arranged at positions different from each other. In addition, no elements are provided in a region between two of the plurality of electrode pads 31 adjacent to each other.

For example, the region in which the plurality of resistors 9 is arranged has a length of approximately 60 μm and a width of approximately 240 μm. Likewise, the region in which the plurality of fuse elements 13 is arranged has a length of approximately 30 μm and a width of approximately 240 μm. The electrode pad 31 has a length of approximately 100 μm and a width of approximately 100 μm. A distance between two of the electrode pads 31 adjacent to each other is approximately 60 μm.

In the semiconductor apparatus 1 of FIG. 7A, the plurality of resistors 9 is arranged in the region under the electrode pad 31. For example, in a semiconductor device having a layout similar to the conventional example of FIG. 7B, if the 60 μm-length and 240 μm-width region for the resistors 9 is divided into three 60 μm-length and 80 μm-width regions, such divided resistor regions can be disposed under the respective electrode pads 31 each having a 100 μm-length and 100 μm-width measurement. This arrangement can eliminate an area of the plurality of resistors 9 of the conventional example of FIG. 7B and therefore the area of the semiconductor device becomes smaller than the area of the conventional example shown in FIG. 7B.

Further, in the semiconductor apparatus 1 of FIG. 7A, each of the fuse elements 13 is arranged in the region between two of the electrode pads 31 adjacent to each other. For example, in a semiconductor device having a layout similar to the conventional example of FIG. 7B, if the 30 μm-length and 240 μm-width region for the fuse elements 13 is divided into three 30 μm-length and 80 μm-width regions, such divided fuse element regions can be disposed in the region having a 100 μm-length and 60 μm-width measurement between two of the fuse elements 13 adjacent to each other. This arrangement can eliminate an area of the fuse elements 13 of the conventional example of FIG. 7B and therefore the area of the semiconductor device becomes further smaller than the area of the conventional example shown in FIG. 7B.

Therefore, with the exemplary measurements described above, the semiconductor apparatus 1 shown in FIG. 7A can be made smaller in area than the conventional semiconductor device of FIG. 7B by approximately 90 μm lengthwise.

As the chip area becomes smaller, a number of chips producible per a wafer is increased, thereby reducing the manufacturing cost.

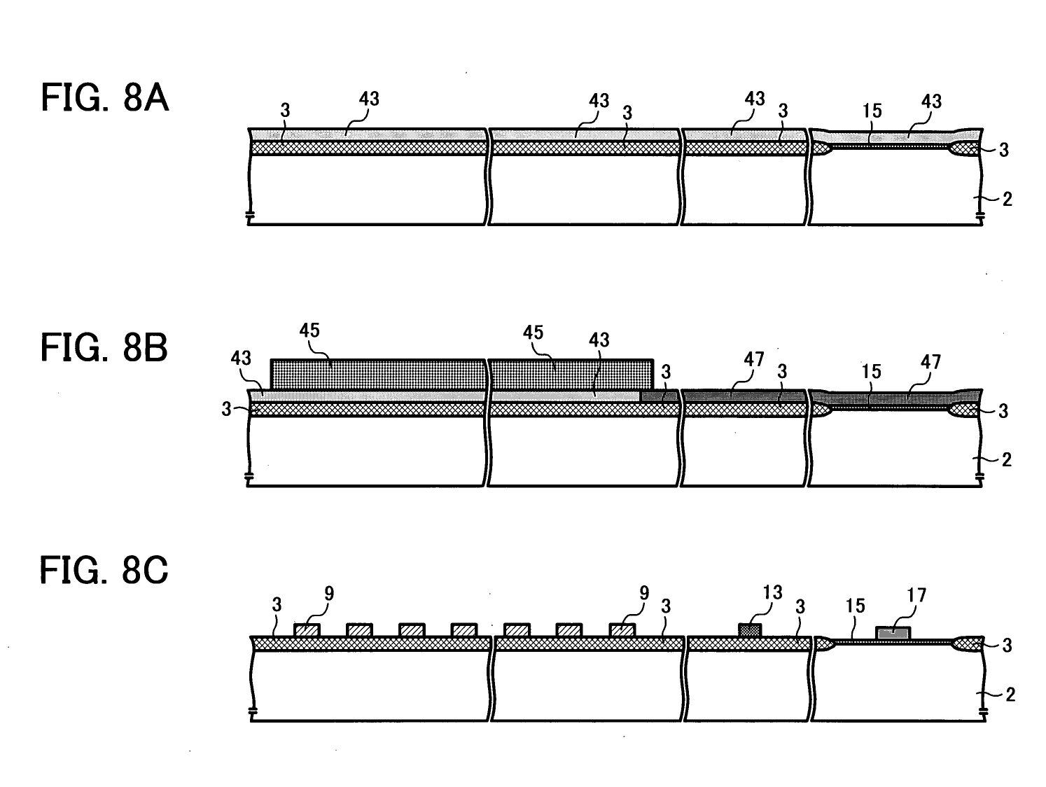

Referring to FIGS. 8A-8C, 9A, 9B and 10, an exemplary manufacturing process is explained for manufacturing the semiconductor apparatus 1 of FIGS. 5A, 5B and 6.

A first process is demonstrated in FIG. 8A, in which the LOCOS oxide film 3 is formed with the LOCOS method on the semiconductor substrate 2 in a wafer state. In this first process, the semiconductor substrate 2 then undergoes a thermal oxidation process to form the gate oxide film 15 in the MOS transistor formation region on the surface of the semiconductor substrate 2. After that, the polysilicon film 43 is formed to have a thickness of approximately 350 nm, for example, on the entire surface of the semiconductor substrate 2 with a low-pressure CVD (chemical vapor deposition), for example. The conditions for the low-pressure CVD include, for example, the temperature in a range from 620° C. to 635° C., the gas for forming a film at a flow rate of SiH₄:H₂=300 sccm:450 sccm, and the pressure of 0.5 Torr. Then, an N-type impurity such as phosphorous is implanted with an ion implantation on the entire surface of the polysilicon film 43 so as to control the resistance value of the polysilicon film 43. The conditions for the ion implantation include, for example, the ion energy of approximately 30 keV, and the dose of approximately 4.3×10¹⁴atoms/cm², in which the dose is controlled within a range from 1×10¹³ atoms/cm² to 1×10¹⁵ atoms/cm².

A subsequent second process is demonstrated in FIG. 8B, in which the oxide film is formed to a thickness of approximately 200 nm on the polysilicon film 43 with the low-pressure CVD and then a masking oxide film 45 is formed with a photo engraving method to cover at least a region forming a resistive element in the resistive-element formation region.

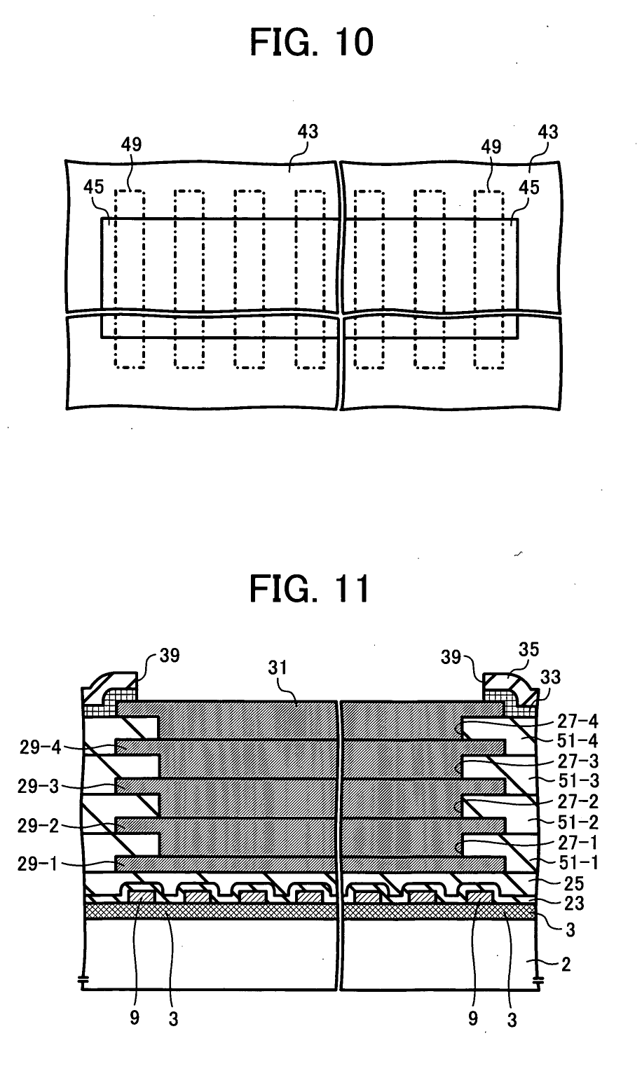

As illustrated in FIG. 10, the masking oxide film 45 is arranged to cover a portion of the polysilicon film 43 in a region of a central side resistive-element in a predetermined formation region 49 for a resistive-element-pattern, but not to cover another portion of the polysilicon film 43 in a region of an edge side resistive-element in the predetermined formation region 49 for the resistive-element-pattern.

The polysilicon film 43 is subjected to deposition and drive diffusion with a phosphorous glass. A portion of the polysilicon film 43 in regions including a low-resistance polysilicon region for a contact by the resistive element, and predetermined formation regions for the fuse element and the gate electrode of the MOS transistor, are implanted densely with phosphorous. Consequently, a low-resistance polysilicon film 47 is formed, as illustrated in FIG. 8B. During this process, amongst the polysilicon film 43 in the predetermined formation region 49 for the resistive-element-pattern, a portion of the polysilicon film 43 in the region of the central side resistive-element is overlaid by the masking oxide film 45 and is therefore not implanted with phosphorous. Another portion of the polysilicon film 43 in the region of the edge side resistive-element in the predetermined formation region 49 for the resistive-element-pattern is implanted with phosphorous to form the low-resistance polysilicon film 47, as illustrated in FIG. 8B.

A subsequent third process is demonstrated in FIG. 8C. In the third process, the masking oxide film 45 is removed and then the polysilicon film 43 and the low-resistance polysilicon film 47 are patterned with the photo engraving method and a dry-etching method. As a result of the patterning, the resistors 9 are formed based on the polysilicon film 43 on the LOCOS oxide film 3 in the resistive-element formation region. Also, the low-resistance polysilicon film 11 is formed based on the low-resistance polysilicon film 47 on both edge sides of the resistors 9. Further, the fuse element 13 is formed based on the low-resistance polysilicon film 47 on the LOCOS oxide film 3 in the fuse-element formation region. Further, the gate electrode 17 is formed based on the low-resistance polysilicon film 47 on the gate oxide film 15 in the MOS transistor formation region and the LOCOS oxide film 3, as illustrated in FIG. 8C.

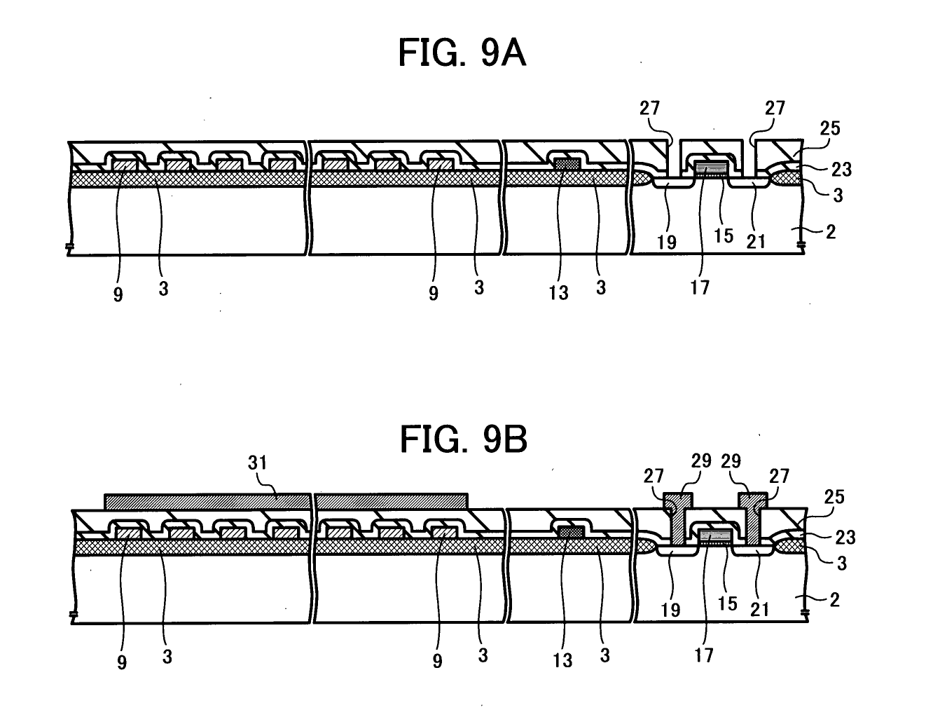

A subsequent fourth process is demonstrated in FIG. 9A. In the fourth process, a resist pattern for forming a high density diffulsion layer is formed, using the photo engraving method to cover at least the formation region for the resistors 9 and to provide an opening in the MOS transistor formation region. Also, the source diffusion layer 19 and the drain diffusion layer 21 are formed on the semiconductor substrate 2 in the MOS transistor formation region by implanting phosphorous or arsenic, for example, under the conditions of ion energy on the order of 30 keV, and the dose of 5.0×10¹⁵ atoms/cm², with the ion implantation method using the resist pattern as a mask for the formation of the high density diffusion layer.

Then, the resist pattern for formation of the high density diffusion is removed. After that, using the CVD method, for example, the NSG film 23 is formed on the entire surface of the semiconductor substrate 2 and subsequently the BPSG film 25 is formed on the NSG film 23. The BPSG film 25 is then subjected to a reflow by a high-temperature heat treatment so as to be planarized.

Then, using photo engraving methods and dry etching methods, the connection holes 27 are formed in the regions corresponding to the low-resistance polysilicon regions 11, the fuse element 13, the gate electrode 17, the source diffusion layer 19, and the drain diffusion layer 21, as illustrated in FIG. 9A.

A subsequent fifth process is demonstrated in FIG. 9B, in which a metal layer including aluminum alloy is formed on the BPSG film 25 and in the connection holes 27 with a spattering method. The metal wiring layer 29 is formed by the process of patterning the metal layer with photo engraving and dry etching, and the electrode pad 31 is formed so as to form the electrode pad 31 which overlays the formation region of the resistors 9, as illustrated in FIG. 9B.

In a subsequent sixth process, the PSG film 33 is formed on the BPSG film 25, the metal wiring layer 29, and the electrode pad 31, with a plasma CVD method, and the SiN film 35 is formed on the PSG film 33. During this process, hydrogen included in an environmental atmosphere when the PSG film 33 and the SiN film 35 are formed and in the PSG film 33 and the SiN film 35 themselves are sealed off by the electrode pad 31. That is, the variations of the resistance value of the resistors 9 due to the invasion of hydrogen to the resistors 9 is prevented.

After the sixth process, with the photo engraving method and the dry etching method, the trimming windows 37 are formed in the SiN film 35, the PSG film 33, the BPSG film 25 and the NSG film 23 corresponding to the formation region of the fuse element 13 and also the pad window 39 is formed corresponding to the formation region of the electrode pad 31 (see FIGS. 5A, 5B and 6).

According to the above-described semiconductor manufacturing method including the first to the sixth processes, the polysilicon film 43 for forming the resistors 9 is used for the fuse element 13 and the gate electrode 17. Therefore, the number of processes of this method is smaller than that of the conventional method in which the resistors 9, the fuse element 13, and the gate electrode 17 are formed based on the respective polysilicon films formed in separate processes.

In the above-described example, phosphorous is used as the impurity for controlling the resistance value of the resistive element. However, the present invention is not limited to phosphorous as the impurity. For example, when a resistive element and a P-channel MOS transistor are formed on the same semiconductor substrate, a polysilicon film impregnated with a P-type impurity is used for a gate electrode of the P-channel MOS transistor. In this process, the resistive element can be formed by using the polysilicon film for forming the gate electrode of the P-channel MOS transistor. Since a P-type impurity such as boron, for example, has atoms with smaller mobility than those of the N-type impurity, it becomes possible to suppress the variations of resistance value due to the heat treatment by using the polysilicon film impregnated with the P-type impurity as the resistive element for the control of the resistance value.

In addition, the material for the resistors 9 is not limited to the polysilicon used in the above-described example. For example, other semiconductor materials such as silicon germanium, silicon chrome, etc., can be used as the material for the resistors 9.

Further, in the second process, the polysilicon film 43 in the predetermined formation region of the low-resistance polysilicon region 11 is impregnated densely with phosphorous so as to be formed as the low-resistance polysilicon film. The present invention, however, is not limited to this method. For example, the following alternative method may be applied: The implantation of phosphorous to the polysilicon film 43 is performed in the second process under the conditions that the entire surface of the predetermined pattern formation region of the resistive element is covered by the masking oxide film 45. Then, in the third process, the polysilicon film pattern for the resistors 9 and the low-resistance polysilicon region 11 is formed based on the polysilicon film 43. Then, in the fourth process, the impurity is implanted to both edge sides of the polysilicon film pattern when the ion is injected to form the source diffusion layer 19 and the drain diffusion layer 21 so that determination of the length of the resistors 9 and the formation of the low-resistance polysilicon region 11 are achieved.

Further, in the example illustrated in FIGS. 5A, 5B and 6, the present invention is applied to a single-layered metal wiring structure. Therefore, the low-resistance polysilicon regions 11 for acquiring the potential of the resistors 9 are disposed outside the formation region of the electrode pad 31. However, the present invention is not limited to this method. For example, when the present invention is applied to a semiconductor apparatus having a multi-layered metal wiring structure, the low-resistance polysilicon region for acquiring the potential of the resistors may be formed within the formation region of the electrode pad and the potential of the low-resistance polysilicon film is acquired by using the metal wiring layer disposed under the electrode pad.

FIG. 11 illustrates a cross-sectional view of formation regions for resistive elements and an electrode pad in one example of a semiconductor apparatus having a five-layered metal wiring structure. As illustrated in FIG. 11, a plurality of the resistors 9 is formed on the LOCOS oxide film 3 on the surface of the semiconductor substrate 2. The NSG film 23 disposed as a lower layer and the BPSG film 25 disposed as an upper layer are formed on the entire surface of the semiconductor substrate 2 and the resistors 9. Also, a first metal wiring layer 29-1 is formed on the BPSG film 25 to cover the formation region of the resistors 9. A first insulating interlayer 51-1 is formed on the BPSG film 25 and the first metal wiring layer 29-1. The first insulating interlayer 51-1 is provided with a connection hole 27-1 at a position corresponding to the first metal wiring layer 29-1 disposed on the resistors 9.

Further, a second metal wiring layer 29-2 is formed in the connection hole 27-1 and on the first insulating interlayer 51-1 in a way corresponding to the first metal wiring layer 29-1.

The second insulating interlayer 51-2, a third insulating interlayer 51-3, and a fourth insulating interlayer 51-4 are sequentially formed on the second metal wiring layer 29-2 and the first insulating interlayer 51-1.

Thus, in the formation region of the resistors 9, the electrode pad 31 is formed, including a third metal wiring layer 29-3 formed on the second insulating interlayer 51-2, a fourth metal wiring layer 29-4 formed on the third insulating interlayer 51-3, and a fifth metal wiring layer 29-5 formed on the fourth insulating interlayer 51-4.

The first, second, third, and fourth metal wiring layers 29-1, 29-2, 29-3, and 29-4 and the electrode pad 31 are connected to each other through a connection hole 27-1 and connection holes 27-2, 27-3, and 27-4.

In this way, the present invention can be applied also to a semiconductor apparatus having, for example, a five-layered metal wiring structure. This semiconductor apparatus is provided with the NSG film 23, the BPSG film 25, the first, second, third, and fourth insulating interlayers 51-1, 51-2, 51-3, and 51-4, and the first, second, third, and fourth metal wiring layers 29-1, 29-2, 29-3, and 29-4 between the electrode pad 31 which is a fifth metal wiring layer and the resistors 9. With this structure, it becomes possible to prevent changing the characteristics of the resistors 9 due to a mechanical impact to the electrode pad 31 during a wire bonding process, for example.

It should be noted, however, that this invention is not limited to the semiconductor apparatus having a five-layered metal wiring structure, described above, but can be applied to another semiconductor apparatus having one or more metal wiring structures.

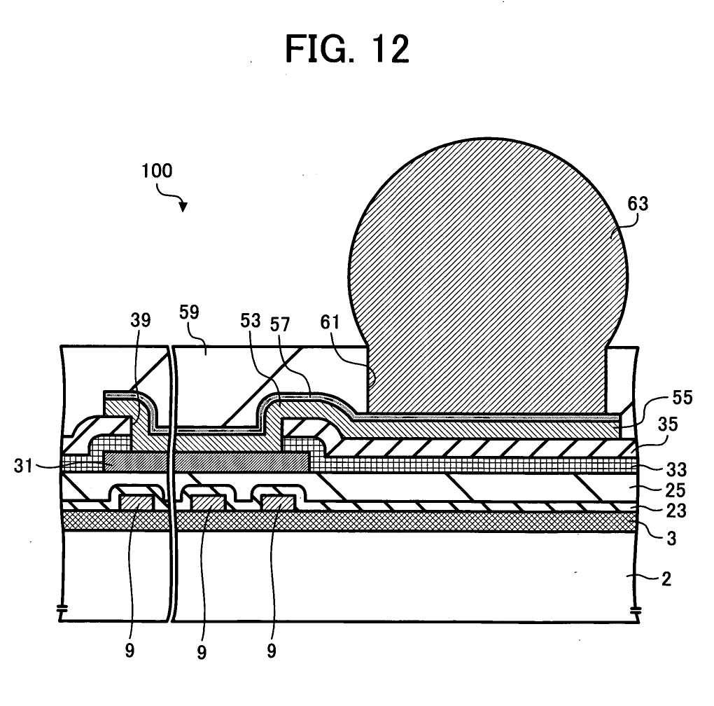

FIG. 12 illustrates a semiconductor apparatus 100 in cross section according to another embodiment of the present invention. This embodiment is a case in which the present invention is applied to a WL-CSP (wafer level-chip size package). A top plan view of the resistive-element formation region in this embodiment is equivalent to that illustrated in FIGS. 5A, 5B and 6. In FIG. 12, components similar to those of the semiconductor apparatus 1 of FIGS. 5A, 5B and 6 in functions and operations are provided with the same reference numerals, and repetitive descriptions for these components are omitted.

As illustrated in FIG. 12, the LOCOS oxide film 3 is formed on the surface of the semiconductor substrate 2, and a plurality of resistors 9 and a plurality of low-resistance polysilicon regions (see reference numeral 11 in FIGS. 5A, 5B and 6) are formed on the LOCOS oxide film 3 in the resistive-element formation region.

The NSG film 23 is formed on the semiconductor substrate 2 and the formation region of the resistors 9, and the BPSG film 25 is formed on the NSG film 23.

The NSG film 23 and the BPSG film 25 are provided with the connection holes (see reference numeral 27 of FIGS. 5A, 5B and 6) at positions corresponding to the low-resistance polysilicon regions disposed to both edge sides of the resistors 9.

The metal wiring layer (see FIG. 5A) is formed in the connection holes 27 and on the BPSG film 25, and the electrode pad 31 is formed on the BPSG film 25 to cover the formation region of the resistors 9. The PSG film 33 is formed on the entire surface of the BPSG film 25, and the SiN film 35 is formed on the PSG film 33. The PSG film 33 and the SiN film 35 form a passivation film. The pad window 39 is formed in the PSG film 33 and the SiN film 35 at a position corresponding to the electrode pad 31.

A second metal wiring layer 53 and a second electrode pad 55 are formed on the SiN film 35 and in the pad window 39. The second metal wiring layer 53 includes an Al-Si alloy including Si of approximately 1 wt % (weight percent). The second metal wiring layer 53 and the second electrode pad 55 form a rerouting layer. A barrier metal layer 57 is formed on the second metal wiring layer 53 and the second electrode pad 55. The barrier metal layer 57 includes a Ti layer having a thickness of approximately 0.1 μm, an Ni layer having a thickness of approximately 0.4 μm, and an Ag layer having a thickness of approximately 0.1 μm.

A polyimide film 59, for example, is formed as a final protection film on the second metal wiring layer 53 and the SiN film 35. Such final protection film may be made of, for example, a polybenzoxazole film instead of the polyimide film 59.

The polyimide film 59 is provided with a second pad window 61 at a position corresponding to the second electrode pad 55. An external connection terminal 63 made of solder, for example, is formed on the second electrode pad 55 via the barrier metal layer 57. The external connection terminal 63 has a top portion protruding through the surface of the polyimide film 59.

In the above-described example, the resistors 9 are arranged in the region under the electrode pad 31, so that the chip size is made smaller. In addition, the external connection terminal 63 is arranged in the region different from the formation region of the electrode pad 31, so that a mechanical impact to the electrode pad 31 is eliminated. As a result, the resistors 9 arranged under the electrode pad 31 are prevented from damage and accordingly the resistors 9 are protected from variations in resistance values.

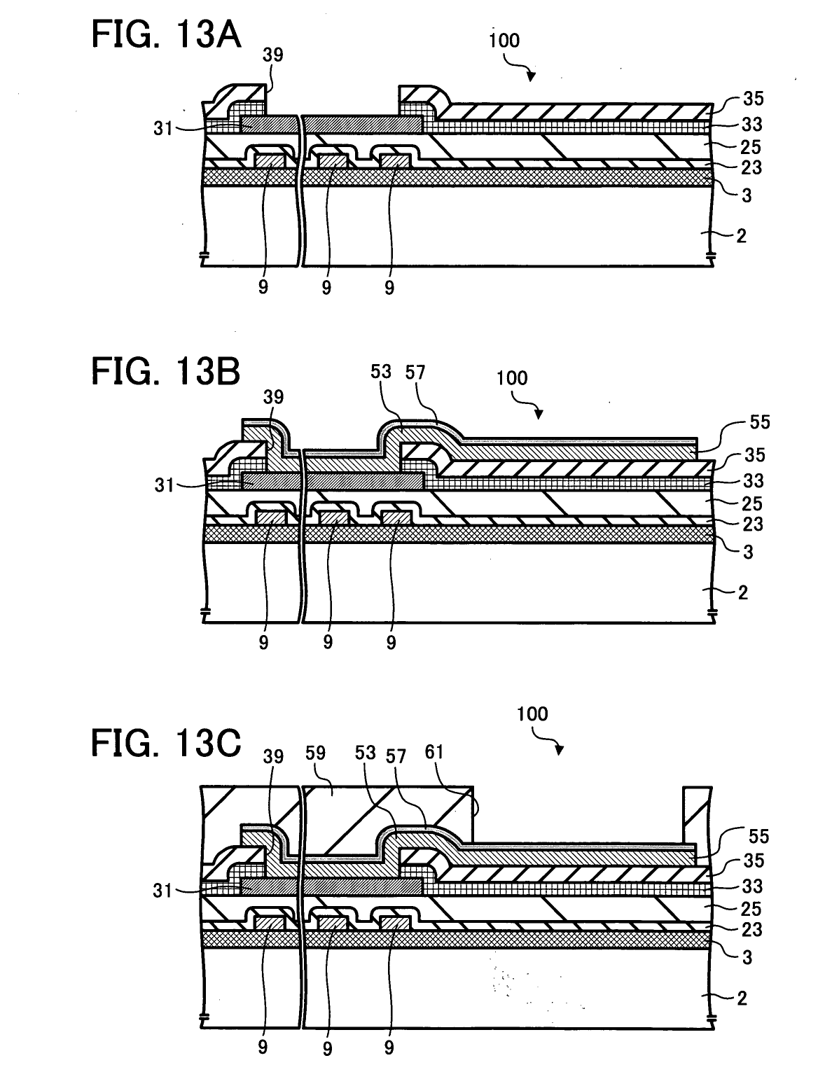

Referring to FIGS. 13A-13C, an exemplary procedure for manufacturing the semiconductor apparatus 100 of FIG. 12 is explained.

FIG. 13A illustrates a first step of the procedure for the semiconductor apparatus 100 of FIG. 12. In the first step, the LOCOS oxide film 3 is formed on the semiconductor substrate 2. Also, the resistors 9 and the low-resistance polysilicon film (not shown) for acquiring the potential of the resistors 9 are formed on the LOCOS oxide film 3. These film formations are carried out in manners similar to those illustrated in FIGS. 8A-8C for the first, second, and third processes of the semiconductor apparatus 1.

Also, the NSG film 23 is formed on the entire surface of the semiconductor substrate 2, and the BPSG film 25 is formed on the NSG film 23: Then, the NSG film 23 and the BPSG film 25 are provided at the predetermined positions with the connection holes (not shown). These formations are carried out in manners similar to those demonstrated in FIG. 9A for the fourth process of the semiconductor apparatus 1.

Further, the electrode pad 31 and the metal wiring layer (not shown) are formed on the BPSG film 25 and in the connection holes, in manners similar to those demonstrated in FIG. 9B for the fifth process of the semiconductor apparatus 1.

Further, the passivation film is formed by sequentially forming the PSG film 33 and the SiN film 35 on the BPSG film 25 and on the formation regions of the electrode pad 31 and the metal wiring layer. After that, the pad window 39 is formed in the SiN film 35 and the PSG film 33 (see FIG. 13A). These formations are carried out in manners similar to those demonstrated in FIGS. 5A, 5B and 6 for the sixth process of the semiconductor apparatus 1.

FIG. 13B illustrates a second step of the procedure for the semiconductor apparatus 100 of FIG. 12. In the second step, the second metal wiring layer 53 and the second electrode pad 55 are formed on the SiN film 35 and in the pad window 39. Then, the barrier metal layer 57 is formed on the upper surface of the second metal wiring layer 53 and on the upper surface of the second electrode pad 55 (see FIG. 13B).

A material suitable for the second metal wiring layer 53 and the second electrode pad 55 is an aluminum alloy layer or copper, for example. The aluminum alloy may be any one of an Al—Si alloy including Si of approximately 1 wt %, an Al—Si—Cu alloy including Si of approximately 1 wt % and Cu of approximately 0.5 wt %, an Al—Cu alloy including Cu of approximately 1 wt %, and an Al—Cu alloy including Cu of approximately 2 wt %, for example.

When an Al—Si alloy including Si of approximately 1 wt % is used as a material for the second metal wiring layer 53 and the second electrode pad 55, an aluminum alloy layer of an Al—Si alloy including Si of approximately 1 wt % is formed to have a thickness of approximately 3 μm with the spattering method, and the barrier metal layer 57 is formed on the above aluminum alloy layer with the spattering method or an evaporation method. The barrier metal layer 57 includes the Ti layer having a 0.1 μm-thickness, the Ni layer having a 0.4 μm-thickness, and the Ag layer having a 0.1 μm-thickness. After that, a resist pattern is prepared in a way corresponding to the wiring pattern, through a resist coating and exposure and development by the photo engraving method. Then, the barrier metal layer 57 is selectively removed using a wet-etching method and the aluminum alloy layer is selectively removed using the dry etching method so as to complete the formation of the second metal wiring layer 53 and the second electrode pad 55. After the etching, the resist pattern is removed with a plasma asher. The barrier metal layer 57 may be made of different combinations of other metal materials such as a combination of Ti, Ni, and Au layers, and Ni, Pd, and Au layers, for example.

When Cu is used as a material for the second metal wiring layer 53 and the second electrode pad 55, a chrome film having an approximately 0.1 μm-thickness and a Cu film having an approximately 0.5 μm-thickness are sequentially formed for protecting Cu from migration and increasing adhesiveness of Cu, using the spattering method. Then, the resist pattern is formed at the positions corresponding to the wiring pattern through the resist coating and exposure and development by the photo engraving method. Then, using an electroplating method, a Cu wiring having an approximately 5 μm-thickness is formed, and Ni of an approximately 3 μm-thickness, Pd of an approximately 0.5 μm-thickness, and Au of an approximately 1 μm-thickness are sequentially formed on the Cu wiring to form the barrier metal layer 57. Using an asher, the resist pattern is removed. After that, the chrome and Cu at portions where the Cu wiring is not formed are removed with the wet etching method, so that the second metal wiring layer 53 and the second electrode pad 55 are completed.

FIG. 13C illustrates a third step of the procedure for the semiconductor apparatus 100 of FIG. 12. In the third step, a negative-type photosensitive polyimide material (e.g., HD4012 manufactured by HD MicroSystems, Ltd.), for example, is coated to an extent of approximately 45 μm using a spin coating method. Then, the negative-type photosensitive polyimide material is exposed to light using a reticulum having a light shielding portion corresponding to the formation region of the second pad window so that a portion of the negative-type photosensitive polyimide material, except for the formation region and a separation region of the second window, is exposed to the light. Then, development is performed, that is, the second pad window 61 is formed to the negative-type photosensitive polyimide material at a position corresponding to the formation region of the second electrode pad 55. After that, a curing operation at the temperature of approximately 320° C. is performed so that the polyimide film 59 having a thickness on the order of 25 μm is formed (see FIG. 13C).

Then, in a fourth step of the procedure for the semiconductor apparatus 100 of FIG. 12, a cream-solder is applied at a position corresponding to the position of the second pad window 61 using a screen printing method and, subsequently, the cream-solder is subjected to heat at a temperature of 260° C. for ten seconds to perform heat melting using an infrared reflow furnace so as to form the external connection terminal 63. Then, the flux used by the screen printing method is removed with a specific cleaning fluid, washed with water, and dried. After that, chips are cut from the thus-processed wafer.

In the above example described with reference to FIGS. 12 and 13A-13C, the present invention is applied to the WL-CSP semiconductor apparatus having the rerouting layer to form the second electrode pad 55 on which the solder-made external connection terminal 63 is formed via the barrier metal layer 57. However, the present invention is not limited to this type of WL-CSP semiconductor apparatus having the rerouting layer and can be applied to other types as well. For example, the present invention can also be applied to another type of WL-CSP semiconductor apparatus having the rerouting layer in which a metal post is formed in a predetermined region of the rerouting layer to protrude from a surface of a sealing layer and an external connection terminal is formed on the protruding metal post. That is, the present invention can be applied to other semiconductor apparatus having the rerouting layer.

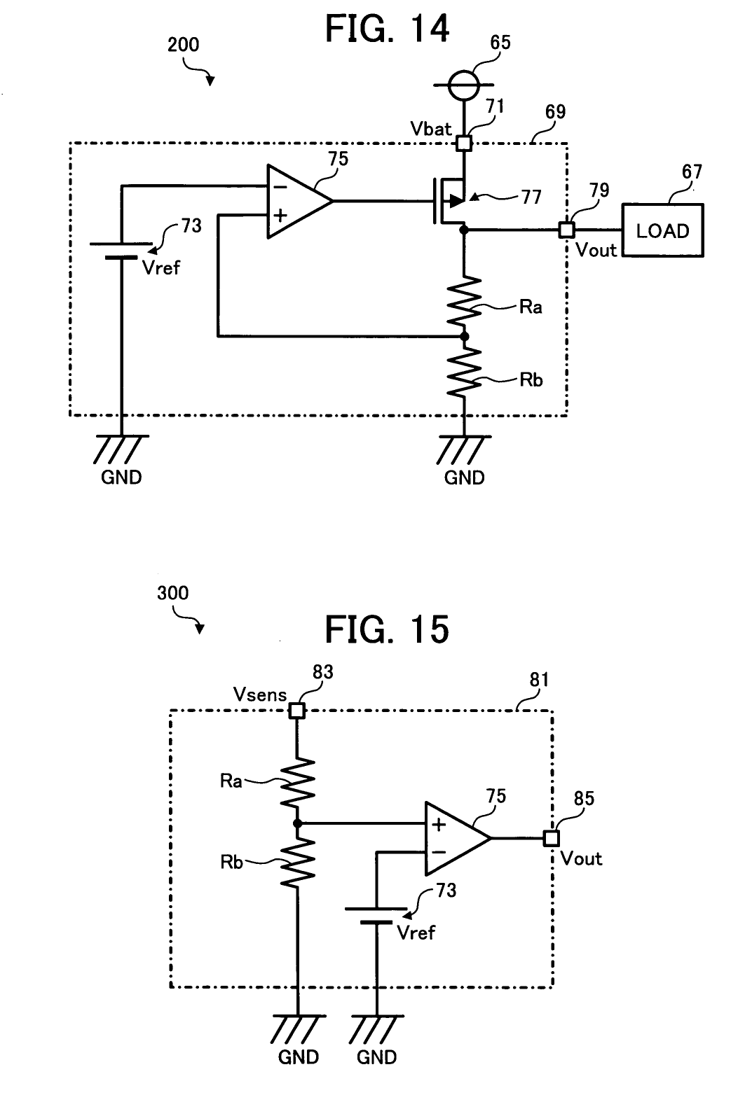

Referring to FIG. 14, a semiconductor apparatus 200 according to another embodiment of the present invention is explained, which has a constant voltage generator in an analog circuit form.

As illustrated in FIG. 14, the semiconductor apparatus 200 is provided with a constant voltage generator 69 for supplying power from a DC (direct current) power supply source 65 to a load 67 in a stable manner. The constant voltage generator 69 includes an input terminal 71, a reference voltage generator 73, an operational amplifier (comparator) 75, a P-channel MOS transistor 77, resistors Ra and Rb, and an output terminal 79. In FIG. 14, Vbat denotes a voltage input from the DC power supply source 65 to a source terminal of the PMOS transistor 77, Vref denotes a reference voltage generated by the reference voltage generator 73, and Vout denotes an output voltage from a drain terminal of the PMOS transistor 77.

The operational amplifier 75 has an output terminal connected to a gate electrode of the PMOS transistor, an inverse input terminal applied with the reference voltage Vref from the reference voltage generator 73, and a non-inverse input terminal applied with a split voltage produced by a division of the output voltage Vout with the resistors Ra and Rb. The operational amplifier 75 operates such that the split voltage from the resistors Ra and Rb becomes equal to the reference voltage Vref.

Referring to FIG. 15, a semiconductor apparatus 300 according to another embodiment of the present invention is explained, which has a voltage detector in an analog circuitry form. As illustrated in FIG. 15, the semiconductor apparatus 300 is provided with a voltage detector 81 including the constant voltage generator 73, the operational amplifier 75, the resistors Ra and Rb, an input terminal 83, and an output terminal 85.

In the voltage detector 81, the operational amplifier 75 has the inverse input terminal applied with the reference voltage Vref from the reference voltage generator 73 and the non-inverse input terminal applied with a split voltage produced by a division of the detected voltage Vsens with the resistors Ra and Rb. The operational amplifier outputs the output voltage Vout through the output terminal 85.

In the above-described voltage detector 81, the output voltage from the operational amplifier 75 is maintained at a high (H) level when the voltage at the terminal to be measured is high and the split voltage produced by a division of the detected voltage Vsens is greater than the reference voltage Vref. The output voltage is changed to a low (L) level when the voltage at the terminal to be measured is reduced. As a result, the split voltage becomes smaller than the reference voltage Vref.

Generally, in the constant voltage generator 69 of FIG. 14 and the voltage detector 81 of FIG. 15, the reference voltage Vref generated by the reference generator 73 varies due to the variations involved in the manufacturing processes. Therefore, to cope with such variations of the reference voltage Vref, the split voltage is adjusted by using a voltage setting circuit capable of changing the resistance value of the split resistor by cutting fuse elements.

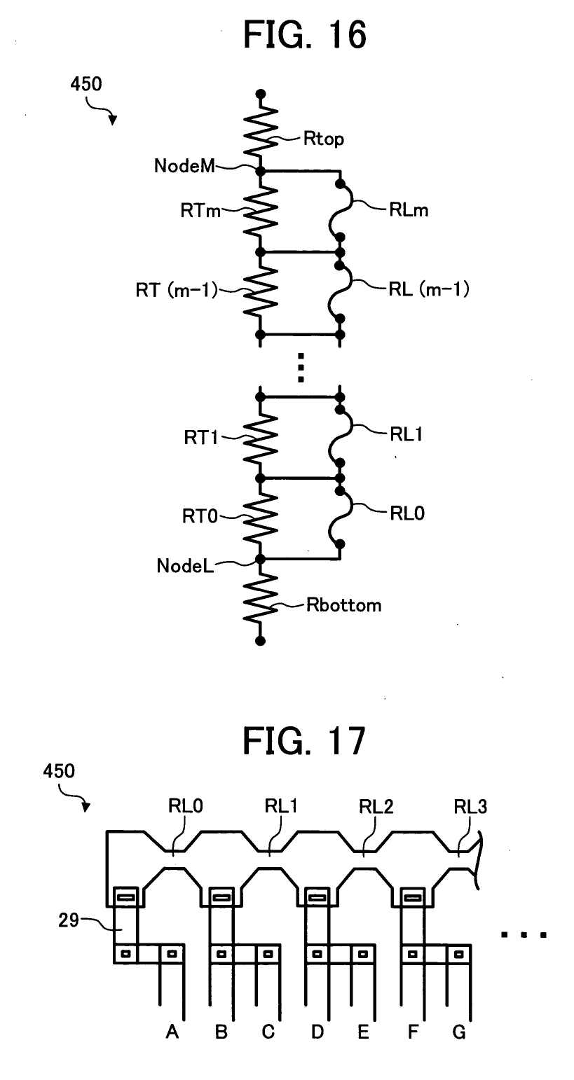

Referring to FIG. 16, a voltage setting circuit 450 in an analog circuitry form is explained, which is integrated in a semiconductor apparatus according to another embodiment of the present invention. As illustrated in FIG. 16, the voltage setting circuit 450 includes resistors Rbottom and Rtop and a number (m+1) of resistors RT0-RTm, wherein m is a positive integer. The resistors Rbottom and Rtop and the number (m+1) of resistors RT0-RTm are connected in series, as illustrated in FIG. 16. The number (m+1) of resistors RT0-RTm are connected with fuse elements RL0-RLm, respectively, in parallel.

FIG. 17 illustrates an exemplary layout of the fuse element portion (i.e., the fuse elements RL0-RLm) of the voltage setting circuit 450. The fuse elements RL0-RLm are made of a polysilicon film having a sheet resistance of from approximately 20Ω to approximately 40Ω. As these fuse elements RL0-RLm, the fuse element 13 of FIGS. 5A and 5B can be used. Although it is not illustrated in FIG. 17, the semiconductor substrate is provided with the trimming window (see reference numeral 37 of FIGS. 5A and 5B) at the position corresponding to the fuse-element formation region.

The number (m+1) of resistors RT0-RTm are given resistance values increasing in a binary order, for example, sequentially from the resistor RL0. That is, when the resistance value of the resistor RT0 is defined as a unit resistance value, the resistance value of the RTn is a value obtained by multiplying the unit resistance value with 2ⁿ, wherein n is a positive integer smaller than m.

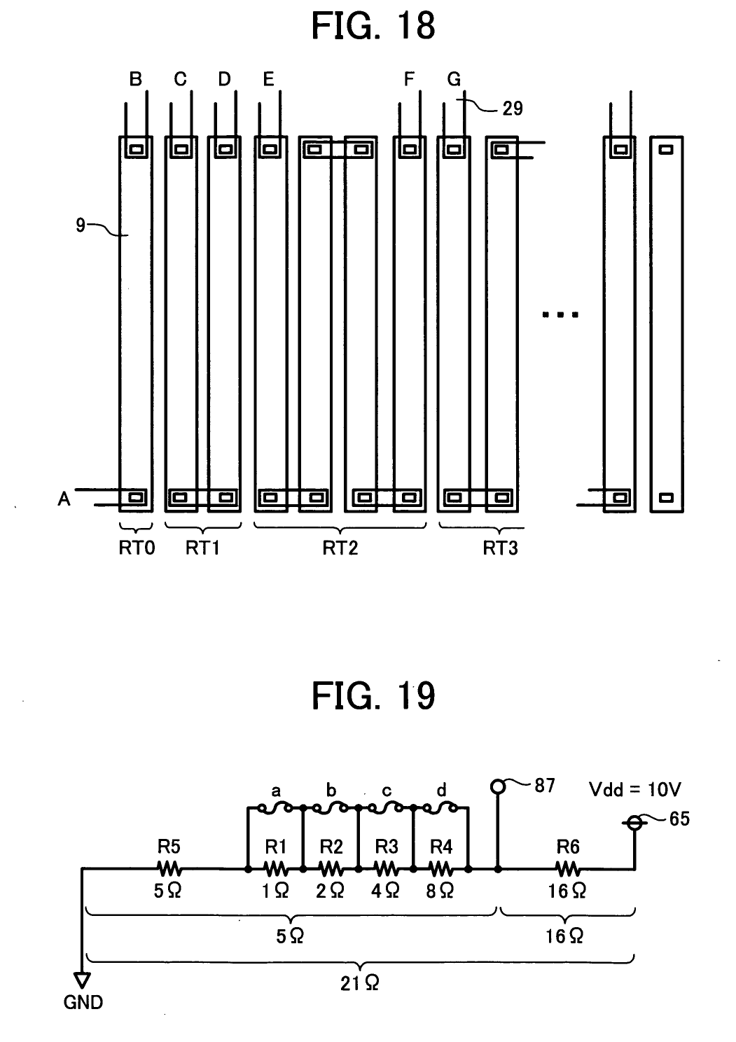

FIG. 18 illustrates an exemplary layout of the resistive element portion (i.e., the resistors RT0-RTm) of the voltage setting circuit 450. For example, as illustrated in FIG. 18, by using the resistors 9 made of the polysilicon pattern, the resistor RT0 is defined as a unit resistance value and is made of a single resistor 9 and the resistor RTn is made of a number (2ⁿ) of the resistors 9. As the resistors 9, those illustrated in FIGS. 5A and 5B, for example, are used. In FIG. 18, the electrode pad disposed on the low-resistance polysilicon formation region for acquiring the potential of the resistors 9 and on the resistors 9 is omitted for clarity.

In FIGS. 17 and 18, the metal wiring layer 29 electrically connects between two each of reference characters A, B, C, D, E, F, and G of FIGS. 17 and 18.

In this way, the voltage setting circuit in which an accuracy of ratios of resistors is significant has the series resistors paired in parallel with series fuse elements in a ladder shape in which a parallel-connected pair of a resistor and a fuse element is defined as a unit resistance value.

With the structure described above, any desired one of the fuse elements RL0-RLm can be cut with a laser beam to make a preferable resistance value available.

Thus, the semiconductor apparatus having the above-mentioned ladder formed resistors according to the present invention can stabilize the resistance value and accordingly increase an accuracy of the output voltage from the voltage setting circuit.

When the voltage setting circuit of FIG. 16 is applied to the resistors Ra and Rb included in the constant voltage generator of FIG. 14, the resistor Rbottom is connected to a ground (GND) and the resistor Rtop is connected to the drain terminal of the PMOS transistor 77. Further, a node L between the resistors Rbottom and RT0 or a node M between the resistors Rtop and RTm is connected to the non-inverse input terminal of the operational amplifier 75.

With the thus-structured voltage setting circuit, the accuracy of the split voltage output from the resistors Ra and Rb is increased and, as a result, the accuracy of the voltage detection performance of the voltage detector 81 is also increased.

Referring to FIGS. 19-22, an exemplary method for setting the output voltage from the voltage setting circuit is explained. As illustrated in FIGS. 19-21, resistors R5 of 5Ω, R1 of 1Ω, R2 of 2Ω, R3 of 3Ω, R4 of 4Ω, and R6 of 6Ω are connected in series between the ground (GND) and the DC power supply source 65. The resistors R1, R2, R3, and R4 are connected in parallel with fuse elements a, b, c, and d, respectively. In addition, an output terminal 87 is connected to a point between the resistors R4 and R6.

In the discussion below, a voltage at the output terminal 87 is sought, wherein the voltage of the DC power supply source 65 is defined as Vdd and is given 10 volts and the ground GND is given 0 volts.

In FIG. 19, the fuse elements a, b, c, and d are not cut and therefore the resistance of the resistors R1-R4 is 0. As a consequence, the following calculations can be made, wherein a resistance between the output terminal 87 and the ground GND is referred to as Routgnd and a resistance between the output terminal 87 and the power supply terminal of the voltage Vdd is referred to as Routvdd; Routgnd=R5=5Ω and Routvdd=R6=16Ω. Therefore, the total resistance is 5Ω+16Ω=21Ω. Accordingly, the output voltage is 10V×5Ω/21Ω≅2.4V.

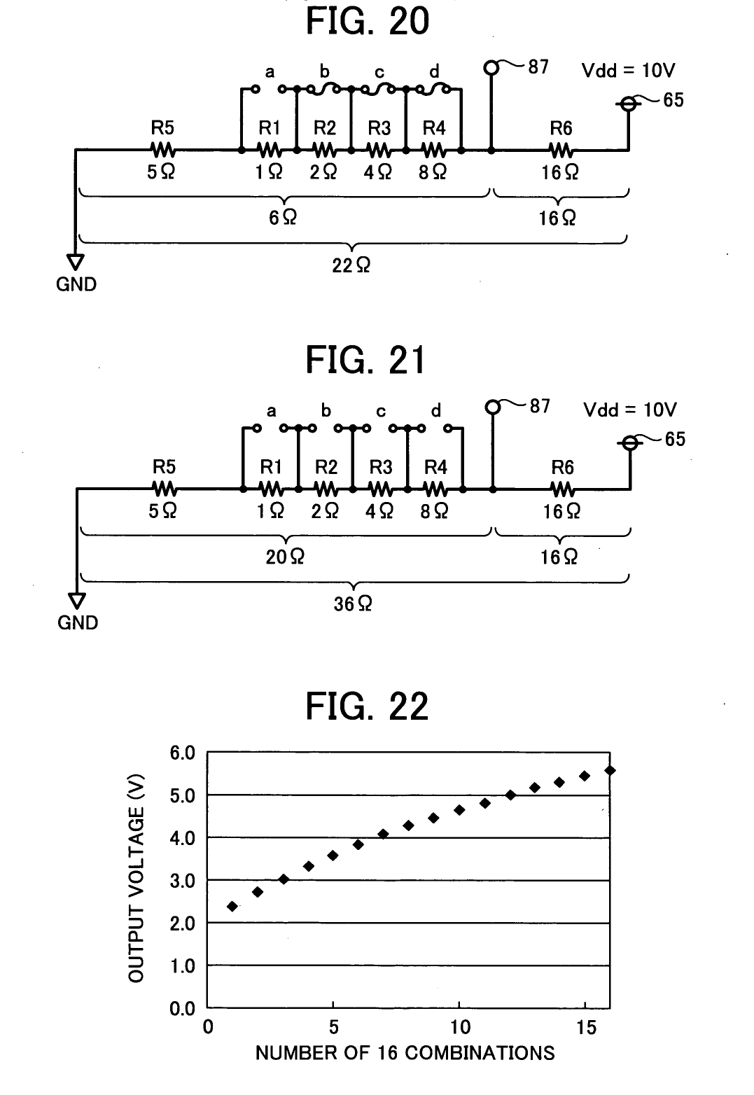

As illustrated in FIG. 20, when the fuse element a is cut, the resistor R1 is made effective between the output terminal and the ground GND. Accordingly, the calculations are made; Routgnd=R1+R5=6Ω and Routvdd=R6=16Ω. Therefore, the total resistance is 6Ω+16Ω=22Ω. Accordingly, the output voltage is 10VΩ×6Ω/22Ω≅2.7V.

That is, the example of FIG. 20 increases the output voltage by 0.3 volts in comparison with the example of FIG. 19.

When all the fiuse elements a, b, c, and d are cut as demonstrated in FIG. 21, the resistors R1-R4 are made effective between the output terminal and the ground GND. Accordingly, the calculations are made; Routgnd=R1+R2+R3+R4+R5=20Ω and Routvdd=R6=16Ω. Therefore, the total resistance is 20Ω+16Ω=36Ω. Accordingly, the output voltage is 10VΩ20Ω/36Ω≅5.6V.

The output value in the example of FIG. 21 increases the output voltage by 3.2 volts in comparison with the example of FIG. 19.

In the above-described structure, each of the fuse elements a, b, c, and d can be selected to be cut or not so that the total of 16 different combinations (i.e., 2×2×2×2=16) can be determined. Table 1 below shows output voltage values for the sixteen different combinations of the fuse elements a, b, c, and d to be cut or not, wherein the sixteen different combinations are given respective numbers 1-16. Also, FIG. 22 demonstrates a graph of a relationship between such output voltage values and the respective sixteen different combinations.

TABLE 1

| Fuse | Resistive Value | | | Output |
|---|---|---|---|---|
| Element No. | d c b a | Routvdd | Routgnd | voltage (V) |
| 1 | 0 0 0 0 | 16 | 5 | 2.4 |
| 2 | 0 0 0 1 | 16 | 6 | 2.7 |
| 3 | 0 0 1 0 | 16 | 7 | 3.0 |
| 4 | 0 0 1 1 | 16 | 8 | 3.3 |
| 5 | 0 1 0 0 | 16 | 9 | 3.6 |
| 6 | 0 1 0 1 | 16 | 10 | 3.8 |
| 7 | 0 1 1 0 | 16 | 11 | 4.1 |
| 8 | 0 1 1 1 | 16 | 12 | 4.3 |
| 9 | 1 0 0 0 | 16 | 13 | 4.5 |
| 10 | 1 0 0 1 | 16 | 14 | 4.7 |
| 11 | 1 0 1 0 | 16 | 15 | 4.8 |
| 12 | 1 0 1 1 | 16 | 16 | 5.0 |
| 13 | 1 1 0 0 | 16 | 17 | 5.2 |
| 14 | 1 1 0 1 | 16 | 18 | 5.3 |
| 15 | 1 1 1 0 | 16 | 19 | 5.4 |
| 16 | 1 1 1 1 | 16 | 20 | 5.6 |

From Table 1 and FIG. 22, it is understood that the output voltage of the voltage setting circuit 450 can be set stepwise from 2.4 volts which is the smallest to 5.6 volts which is the greatest.

In the above-described example, the number of fuse elements is four. The present invention is not limited to the four fuse elements and any number of fuse elements can be applicable. In fact, by increasing the number of fuse elements, it becomes possible to increase the accuracy of the adjustment of the output voltage. For example, when the voltage setting circuit 450 uses ten fuse elements, it can change the outputvoltage in 1024 ways (i.e., tenth power of 2).

Numerous additional modifications and variations are possible in light of the above teachings. It is therefore to be understood that within the scope of the appended claims, the disclosure of this patent specification may be practiced otherwise than as specifically described herein.

1. A semiconductor apparatus, comprising:
a semiconductor substrate;
an electrode pad including a metal layer and formed on the semiconductor substrate;
a MOS transistor formed on the semiconductor substrate; and
an analog circuit formed in a region under the electrode pad on the semiconductor substrate and comprising a resistive element including a semiconductor material.

2. A semiconductor apparatus according to claim 1, wherein the resistive element includes a specific material made of one of polysilicon, silicon germanium, and silicon chrome.

3. A semiconductor apparatus according to claim 1, wherein the resistive element includes a plurality of resistors.

4. A semiconductor apparatus according to claim 1, wherein the MOS transistor comprises a gate electrode including the specific material of the resistive element.

5. A semiconductor apparatus according to claim 1, further comprising:
an insulating film formed on the semiconductor substrate in a region in a vicinity of the electrode pad; and
a fuse element formed on the insulating film.

6. A semiconductor apparatus according to claim 5, wherein the insulating film includes the specific material of the resistive element.

7. A semiconductor apparatus according to claim 5, further comprising:
a rerouting layer formed in a region above the fuse element; and
an external connection terminal formed on the rerouting layer in a region different from a formation region of the electrode pad.

8. A semiconductor apparatus according to claim 5, wherein the analog circuit comprises a voltage setting circuit, the resistive element comprises at least two resistors for producing a split voltage based on an input source power voltage, and the voltage setting circuit changes the split voltage according to a condition of the fuse element.

9. A semiconductor apparatus according to claim 1, wherein the resistive element comprises at least two resistors for producing a split voltage based on an input source power voltage, the analog circuit comprises a reference voltage generator for generating a reference voltage and a voltage detector including a comparator for performing a comparison of the split voltage with the reference voltage.

10. A semiconductor apparatus according to claim 9, wherein the analog circuit further comprises an output driver for controlling an output voltage based on an input voltage, and the comparator of the voltage detector outputs a gate control voltage as a result of the comparison for controlling the output driver to control the output voltage.

11. A method of manufacturing a semiconductor apparatus including a MOS transistor and an analog circuit having a resistive element including a semiconductor material, the method comprising the steps of:
providing a semiconductor substrate;
forming an insulating film on the semiconductor substrate;
forming a semiconductor material film on an entire surface of the semiconductor substrate including a formation region of the insulating film;
implanting an impurity in the semiconductor material film to acquire a predetermined resistance value;
forming a resistive element on the insulating film by patterning the semiconductor material film;
forming a first insulating layer on an entire surface of the semiconductor substrate including a formation region of the resistive element; and
forming an electrode pad including a metal layer on the first insulating layer including the formation region of the resistive element.

12. A method according to claim 11, wherein the resistive element includes a specific material made of one of polysilicon, silicon germanium, and silicon chrome.

13. A method according to claim 11, wherein the step of forming the resistive element forms the resistive element in a predetermined formation region of the resistive element and the resistive element includes a plurality of resistors.

14. A method according to claim 11, further comprising the steps of:
forming a second insulating layer having an opening at a position corresponding to a formation region of the electrode pad after the step of forming the electrode pad;
forming a rerouting layer on the electrode pad and the second insulating layer; and
forming an external connection terminal on the rerouting layer in a region different from the formation region of the electrode pad.

15. A method according to claim 11, wherein the step of forming the resistive element forms a gate electrode on the insulating film in a formation region of the MOS transistor based on the semiconductor material film.

16. A method according to claim 11, wherein the step of forming the resistive element forms a fuse element on the insulating film in a region different from the formation region of the resistive element based on the semiconductor material film.
